(19) United States
(12) Patent Application Publication
(10) Pub. No.: US 2007/0238240 A1
(43) Pub. Date: Oct. 11, 2007

(54) Method of forming a transistor in a non-volatile memory device

(76) Inventors: Dominik Olligs, Dresden (DE); Florian Beug, Dresden (DE); Ricardo Pablo Mikalo, Waltersdorf (DE)

Correspondence Address: SLATER & MATSIL LLP, 17950 PRESTON ROAD, SUITE 1000, DALLAS, TX, 75252, US

(21) Appl. No.: 11/392,240

(22) Filed: Mar. 29, 2006

(51) Int. Cl. H01L 21/8238

(52) U.S. Cl. 438/216

(57) ABSTRACT

A field-effect transistor is formed that has spacers formed by etching openings into a conductive layer and filling the openings with spacer material. The openings are formed together with a gate web in the conductive layer, wherein the gate web is surrounded by the openings on at least two sides. The spacers serve to define lightly doped drain regions arranged in the underlying substrate between a highly doped drain region and a channel region of the transistor. The transistor thus formed is specifically suited for providing high-voltage currents to memory cells of a non-volatile memory array.

### TECHNICAL FIELD

The invention relates to a method of forming a high-voltage field-effect transistor of a memory device such as a non-volatile memory device, particularly a charge-trapping memory device.

### BACKGROUND

Memory cells of a flash memory array are based on trapping of charge carriers in a floating gate or in a dielectric memory layer confined by thin confinement layers, e.g., an ONO-layer sequence. These non-volatile memory cells are electrically programmable and erasable.

The development of flash memory devices comprising such arrays undergoes a continuing decrease in structure sizes. Currently, the NAND-flash technology tends towards structure sizes of 70 nm, whereas the NOR-technology tends towards 90 nm of structure sizes. As a flash memory cell is substantially formed of a field-effect transistor, which comprises the floating gate or ONO-charge-trapping layer adjacent to its gate conductor, memory cell sizes directly scale with the transistor size.

An array of memory cells is generally controlled by logic located in a periphery of the array. This logic also comprises transistors. In the technical field of non-volatile memory, programming or erasing operations with regard to the storage content of memory cells are often performed applying high voltages to those lines (bitlines, wordlines, platelines, etc.) which address respective memory cells. Accordingly, there is a need for high voltage transistors in non-volatile memory, particularly flash memory, but also, e.g., other non-volatile memory types such as FeRAM or MRAM. These voltages may exceed for example 3V.

Such high-voltage transistors particularly deviate from memory cell transistors in that the corresponding diffusion or source/drain regions have a larger lateral extent. The diffusion regions comprise highly doped drain regions (HDD) and lightly doped drain regions (LDD), wherein the LDD regions are placed within the substrate between a channel region of the transistor and the HDD region. The LDD region is provided to reduce the field strength gradient at the pn-junction. As the voltages are higher in the case of high-voltage transistors, the LDD regions must, therefore, be arranged with a larger size as compared with memory cell transistors.

In the case of memory cell transistors, LDD regions are formed, for example, by means of a sidewall spacer technique, according to which an HDD implant is recessed from a respective gate stack. With regard to the high-voltage transistors a former approach was to provide a dedicated photomask which, specifically for the purpose of structuring spacers to protect the LDD region formed underneath, was used to expose a resist and to lithographically structure the layers thereunder in order to form the spacer.

However, this approach has led to asymmetric transistor geometries when structures formed by a first photomask, which defines the gate stack, has some misalignment with the above-mentioned second photomask, which is suited for defining the spacer structures protecting the LDD regions. For example such a misalignment may lead to different properties between the source and drain regions.

To inhibit such alignment issues, a proper biasing would be necessitated in order to secure similar electrical properties of both diffusion regions. Such biasing, however, results in larger design rules with respect to the transistor geometry.

With decreasing structure widths a transition towards forming the LDD spacers as sidewall spacers has thus occurred. Herein, the sidewall spacers are formed at sidewalls of the gate stack by means of depositing an isolating layer (oxide or nitride) of conformal thickness. An anisotropic etching removes horizontal parts of this layer, while vertical parts at the sidewalls are retained. As a result, the width of the LDD region-forming spacer is in scale with the thickness of the conformal layer. An advantage arises from the fact, that no specific photomask needs to be provided in order to define the spacers.

Aspect ratios of a gate stack, on which the conformal layer is deposited, must be kept in a defined range. As structure widths further decrease (towards 90 or 70 nm) the height of the gate stack must also necessarily decrease. As a result thereof, the maximum thickness of the conformal layer also decreases and the lateral extent of a spacer is reduced below a limit, which is necessary to support the reliability of a transistor with regard to field strength gradients.

### SUMMARY OF THE INVENTION

Therefore, a need arises to retain LDD region-forming spacers of sufficient size, but without necessitating additional photomasks to produce such spacers.

In accordance with one aspect of the invention, there is provided a method of forming a transistor in a charge-trapping memory, comprising: covering a substrate with a gate dielectric layer; depositing a first conductive layer upon the gate dielectric layer; etching the first conductive layer in order to form openings therein, which enclose a first web in the first conductive layer, the first web forming a bottom part of a gate stack of the transistor, the openings being surrounded by further portions of the first conductive layer, which are not removed; implanting the substrate in a region exposed by the openings to form lightly doped drain regions in the substrate adjacent to the gate stack; filling the openings with a spacer material to form each a spacer between the first web and the further portions of the first conductive layer; depositing a second conductive layer upon the first web and the further portions of the first conductive layer and upon the spacer; etching the second and the first conductive layer in order to remove the further portions of the first conductive layer and to form a second web in the second conductive layer, which is located upon the first web, the second web forming an upper part of the gate stack; and implanting the substrate in regions where the further portions have been removed to form highly doped drain regions.

In accordance with another aspect, there is provided a method of forming a high-voltage field-effect transistor in a periphery of a charge-trapping memory cell array, which comprises low-voltage field-effect transistors, comprising: covering a semiconductor substrate with a first conductive layer; forming openings in the first conductive layer by means of lithographic structuring using a first photomask, the openings surrounding a gate web; doping the substrate within the openings to form lightly doped drain regions and forming a spacer in each of the openings by means of filling the opening due to deposition; providing a second photomask in order to remove portions in the first conductive layer selectively with respect to the spacer and with respect to the gate web being protected using the first photomask; and doping the substrate where portions of the first conductive layer have been removed to form highly doped drain regions.

In accordance with a further aspect, there is provided a method of forming a field-effect transistor, comprising: providing a substrate covered with at least a conductive layer; forming a first web in the conductive layer, which represents a bottom part of a gate stack and which is separated from further portions of the conductive layer by means openings; forming lightly doped drain regions within the substrate and below the openings; filling the openings to form spacers therein; selectively removing the further portions of the first conductive layer adjacent to the spacers excluding the web; and forming highly doped drain regions within the substrate in surface regions, where the further portions of the first conductive layer have been removed.

In accordance with a further aspect of the invention, there is provided a field-effect transistor, comprising: a substrate; a gate dielectric layer formed on the substrate; a first gate web formed upon the gate dielectric layer; spacers formed adjacent to and on the both sides of the first gate web; lightly doped drain regions formed in the substrate below the spacers; and highly doped drain regions formed in the substrate adjacent to the lightly doped drain regions, wherein the spacers have a width larger than the width of the first gate web.

According to embodiments, a spacer protecting a lightly doped drain (LDD) region when performing an implant or doping the highly doped drain region is formed by means of lithographic structuring using, e.g., a photomask. The structuring is performed in a conductive layer, which is used to form a bottom part of a gate stack. In order to form the spacers, the openings are filled with spacer material, for example oxide and/or nitride. The spacer material is then planarized. The openings such defined simultaneously enclose the gate web, which is formed by the retained parts of the conductive layer between the openings. Consequently, one and the same photomask is used to define the gate stack and the position of the spacers. No additional photomask is thus necessary to form lightly doped drain regions.

Furthermore, the web and the openings may be provided with structure widths as desired. In particular, the widths of the openings (and thus the LDD forming spacers) may be chosen independently of the size (width or height) of the gate stack.

According to embodiments of the invention, the gate stack comprises at least a bottom and an upper part, wherein the bottom part represents a conductive layer in which the openings are formed that are filled with the spacer material. An upper part (which is not necessarily the uppermost part of conductive portions within the gate stack) is deposited and structured subsequently using a second photomask. As this second photomask merely relates to the memory cell periphery, the structure widths may be provided at a somewhat larger level. In particular, this upper part of the gate stack may have a width larger than that of the bottom part. This may even be necessary as the etching of the diffusion regions (HDD regions) necessitates removing a corresponding second and first conductive layer such that the photomask has to shield the already structured bottom part of the gate stack enclosed between the two spacers.

It is clear to a person skilled in the art and pertaining to the technical field of semiconductor manufacturing, that the aspects and embodiments as detailed herein shall not be limited to the production of high-voltage field-effect transistors. There are many other applications that are known to require large spacers adjacent to a transistor gate. Those other applications and methods of forming the same are considered being included by the scope of the invention.

The invention will become clearer with respect to certain embodiments when taken in conjunction with the accompanying drawings.

### BRIEF DESCRIPTION OF THE DRAWINGS

For a more complete understanding of the present invention, and the advantages eof, reference is now made to the following descriptions taken in conjunction with the ompanying drawing, in which:

FIGS. 1-6 illustrate in a sequence of side views of a field-effect transistor method of an embodiment according to the invention;

FIG. 7 shows in a top view schematically the transistor geometry and the position hotomask structures with respect to the transistor in an exposure.

The following list of reference symbols can be used in conjunction with the figures:

| | |
|---|---|
| 1 | transistor |
| 2 | substrate |
| 4 | gate dielectric layer |
| 6 | first conductive layer |
| 8 | first gate web |
| 9 | further portions of first conductive |
| | layer |
| 10a, 10b | openings |
| 12 | first photomask |
| 14a, 14b | LDD regions |
| 16 | sidewall spacers |
| 18 | second conductive layer |
| 20 | spacer material |
| 22 | second gate web |
| 24 | second photomask |
| 26a, 26b | HDD regions |
| 28 | diffusion contacts |
| 30 | gate contact |
| 32 | overlap region |
| 34 | isolation (STI) |

### DETAILED DESCRIPTION OF ILLUSTRATIVE EMBODIMENTS

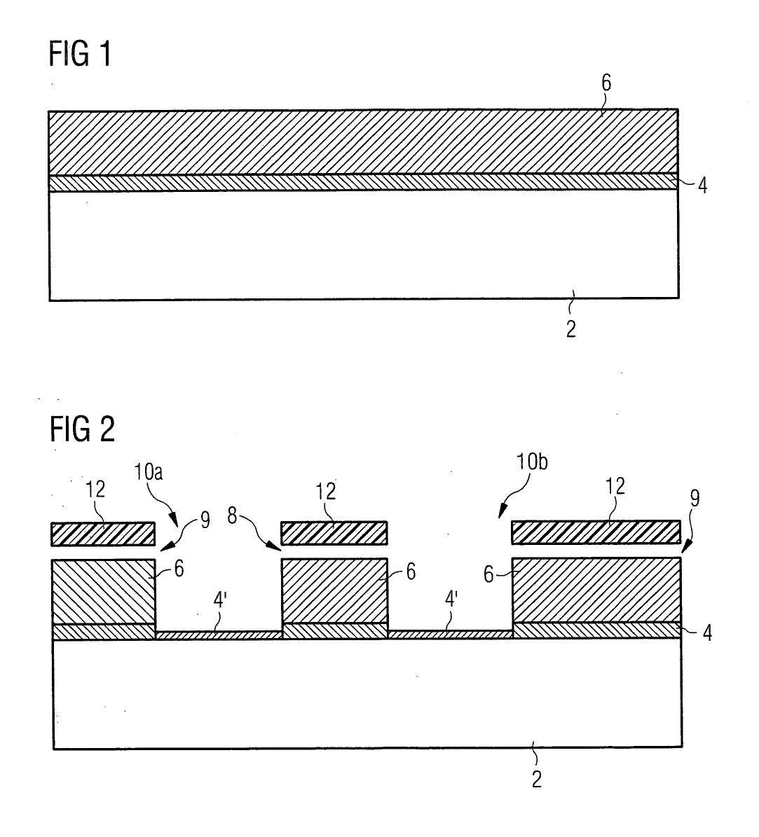

FIGS. 1-6 illustrate in a sequence of side views, method steps according to an embodiment of the invention. A substrate 2 is provided, which is covered with a dielectric layer 4 and a conductive layer 6. The substrate 2 is made of monocrystalline silicon and may comprise a well region (not shown) that has been formed by implanting or doping the substrate in a previous method step. The dielectric layer 4 may refer to an oxide layer grown on the substrate by means of oxidation. The conductive layer 6 may comprise polysilicon, which is, e.g., doped to provide sufficient conductivity to the gate stack to be formed. The substrate 2 may refer to a semiconductor wafer.

FIG. 2 shows a situation after a photomask 12 has been provided (schematically drawn above the substrate), and a lithographic structuring is performed to yield openings 10a, 10b in the conductive layer 6. The lithographic structuring may involve exposing and projecting structures formed on the photomask 12 onto a resist layer deposited upon the substrate (or wafer), developing the resist and transferring the resist pattern into the conductive layer 6 by means of anisotropic etching. The etching stops on a dielectric layer 4, wherein regions 4′ of the dielectric layer 4 are slightly thinned. The etching may be carried out with a selectivity of polysilicon with regard to an oxide or nitride, etc. The openings 10a, 10b, thus formed enclose a first gate web 8 in the conductive layer 6. Other portions 9 in the conductive layer 6 surround the openings 10a, 10b, but will be removed in a later method step.

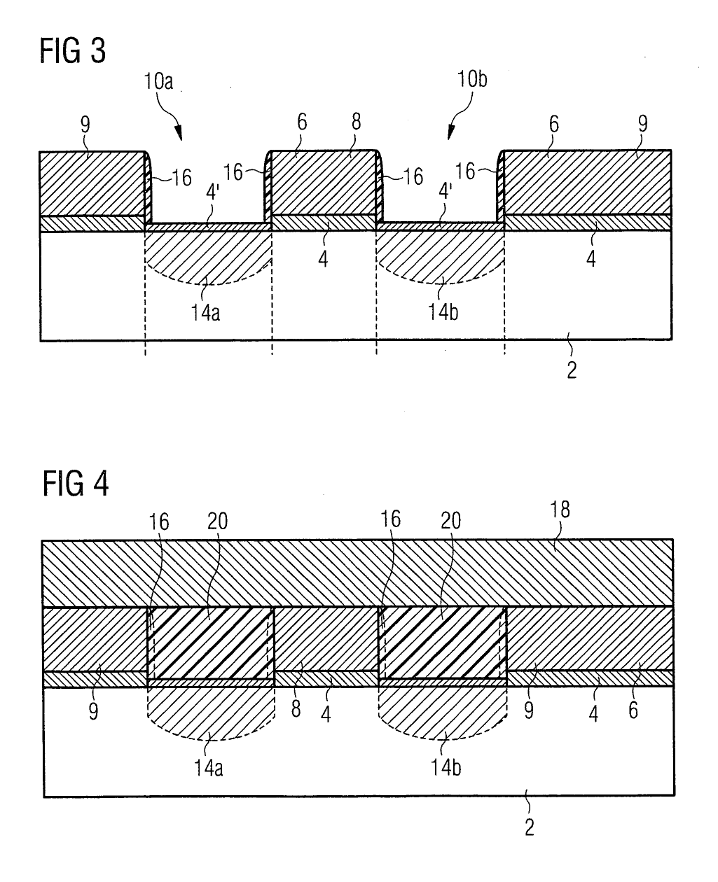

FIG. 3 shows the formation of the lightly doped drain (LDD) regions 14a, 14b. In a first step, sidewall spacers 16 are formed at the sidewalls of the openings, i.e., at the gate web 8 and the further portions 9 of the conductive layer 6. The sidewall spacers 16 serve to recess the LDD regions 14a, 14b as desired by design from a channel region of the transistor. Optionally, sidewall spacers 16 may be formed by means of depositing a conformal layer (e.g., an oxide or a nitride) followed by anisotropic etching. LDD regions 14a, 14b are then produced by implanting the substrate 2 with dopants in accordance with the desired electrical characteristics of the transistor.

The implant dose and the conductivity type of dopants may be chosen as in the conventional case.

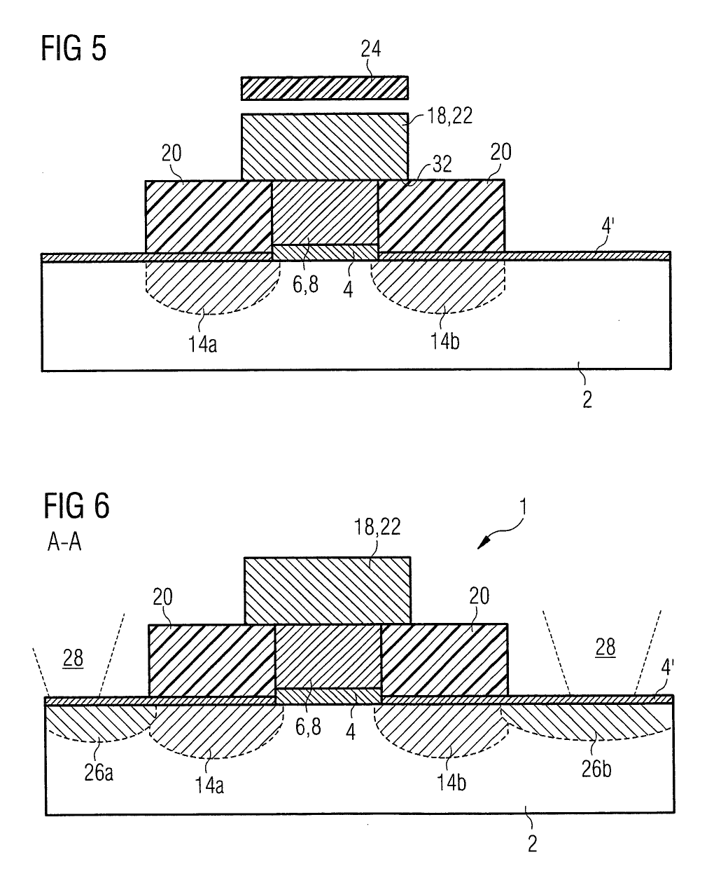

FIG. 4 shows the situation after filling a spacer material 20, e.g., an oxide or a nitride or an oxynitride, etc., into the openings 10a, 10b. Therein, the openings 10a, 10b are completely filled. Thereafter, a planarization is performed (e.g., chemical mechanical polishing, or alternatively a suitable etch step with a stop on the conductive layer 6) such that a surface is provided by the conductive layer 6 and the spacer material 20. Next, a second conductive layer 18 is deposited upon the planarized surface.

FIG. 5 shows the results of a second lithographic structuring step using a photomask 24. Again, a resist layer is deposited and exposed with a pattern from the photomask 24. A second gate web 22 is produced thereby, which covers the first gate web 8 and further portions of the spacer material 20. The corresponding etching is performed with selectivity to the material of the conductive layers 18 and 6, while spacer material 20 and the dielectric layer 4, 4′ are retained, respectively. Conductive layers 6, 18 may be of the same material, i.e., polysilicon in this embodiment.

Nevertheless, it is also possible that the first conductive layer 6 is made of polysilicon, for example, and the second conductive layer 18 comprises a metal, such as tungsten or a tungsten silicide, or aluminum, etc. In this latter case, two subsequent etch steps may be performed. It is important that the further portions 9 and the material deposited upon the further portions is efficiently removed from the substrate surface.

FIG. 6 shows the results of an implant step, wherein a resist mask, such as that applied in the previous lithographic step shown in FIG. 5, may have been employed. The substrate 2 is implanted to produce highly doped drain regions (HDD regions) 26a, 26b adjacent to the LDD regions 14a, 14b.

Substantial components of the transistor 1 are thus formed. Further steps relate to providing a sidewall and/or cap isolation to the gate stack, forming an isolation layer towards a next metal level, and providing contacts 28, 30 to the diffusion regions and the gate stack.

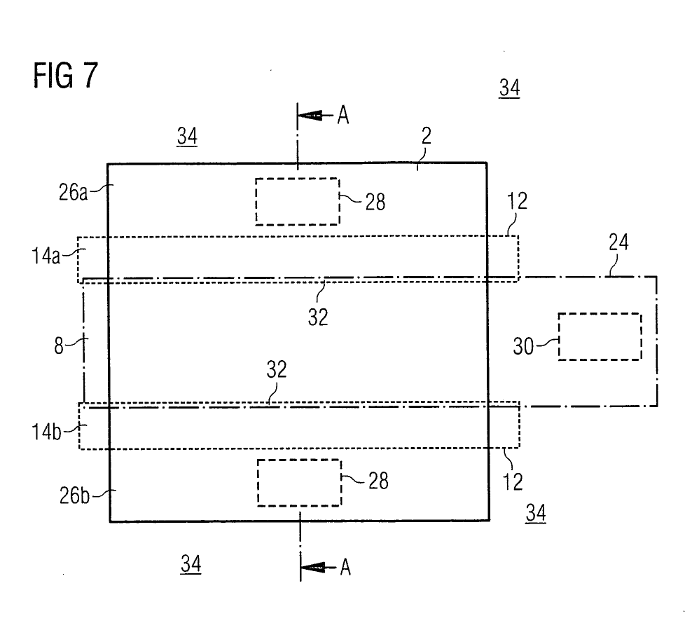

The layout of the transistor geometry is shown in FIG. 7. A line AA indicates the position of the side view shown in FIG. 6. In the schematical drawing shown in FIG. 7 the position of respective photomasks 12, 24 is indicated by the dotted and dash-dotted lines. It is visible herein, that a gate stack being processed in a dual poly planar (DPP) manner (i.e., two polysilicon layers deposited on top of each other and planarized, respectively) necessitates an overlap 32 between structures projected from the photomask 24 and the spacers 20, which are defined by photomask 12. The reason is that both conductive layers 6, 18 are then etched in the same step and the (first) gate web has thus to be shielded by the second mask.

However, it will become clear that this overlap 32 is not necessary, if conductive layers 6, 18 are of different material, such as polysilicon or tungsten silicide.

It is noted that the substrate area 2 shown in the top view of FIG. 7 is effectively an active area bounded by an STI-region 34 (STI shallow trench isolation). To form the STI region, a trench is etched into the substrate 2, which is then filled with isolating material such as an oxide. Other techniques than an STI used to define the active area of the present field-effect transistor by means of forming an isolation may similarly be employed.

What is claimed is:

1. A method of forming a transistor in a charge-trapping memory, the method comprising:
covering a substrate with a gate dielectric layer;
depositing a first conductive layer over the gate dielectric layer;
etching the first conductive layer in order to form openings therein, the openings enclosing a first web in the first conductive layer, the first web forming a bottom part of a gate stack of the transistor, the openings being surrounded by further portions of the first conductive layer that are not removed;
implanting the substrate in a region exposed by the openings to form lightly doped drain regions in the substrate adjacent to the gate stack;
filling the openings with a spacer material to form each a spacer between the first web and the further portions of the first conductive layer;
depositing a second conductive layer over the first web and the further portions of the first conductive layer and over the spacer;
etching the second and the first conductive layers in order to remove the further portions of the first conductive layer and to form a second web in the second conductive layer, the second web being located over the first web, the second web forming an upper part of the gate stack; and
implanting the substrate in regions where the further portions have been removed to form highly doped drain regions.

2. The method according to claim 1, wherein the spacer material comprises an oxide or a nitride.

3. The method according to claim 1, wherein the step of etching the first conductive layer includes providing a first photomask and the step of etching the second and the first conductive layers includes providing a second photomask, each of the photomasks being used to project a pattern into a resist deposited over respective layers, the resist being developed to provide an etch mask for the etching.

4. The method according to claim 1, wherein the step of depositing the first conductive layer comprises depositing polysilicon.

5. The method according to claim 4, wherein the step of depositing the second conductive layer comprises depositing at least one of tungsten or tungsten silicide.

6. The method according to claim 1, further comprising depositing a conformal layer of a further material within the openings prior to implanting the substrate and filling the openings with the spacer material in order to form sidewall spacers within the openings, which provide an implant recessed from sidewalls of the openings.

7. The method according to claim 6, wherein the sidewall spacers are formed by depositing an oxide.

8. The method according to claim 3, wherein the step of providing the first photomask and subsequent etching includes etching openings having a width of at least 60 nm.

9. A method of forming a high-voltage field-effect transistor in a periphery of a charge-trapping memory cell array that includes low-voltage field-effect transistors, the method comprising:
covering a semiconductor substrate with a gate dielectric layer a first conductive layer;
forming openings in the first conductive layer by means of lithographic structuring using a first photomask, the openings surrounding a gate web;
doping the substrate within the openings to form lightly doped drain regions and forming a spacer in each of the openings by means of filling the opening;
providing a second photomask in order to remove portions in the first conductive layer selectively with respect to the spacer and with respect to the gate web; and
doping the substrate where portions of the first conductive layer have been removed to form highly doped drain regions.

10. The method according to claim 9, further comprising forming conductive contacts in electrical contact with the highly doped drain regions.

11. The method according to claim 9, further comprising planarizing a surface of the first conductive layer and the spacers after filling the openings due to deposition.

12. The method according to claim 11, further comprising:
depositing a second conductive layer over the planarized first conductive layer and the spacers; and
using the second photomask to further remove portions of the second conductive layer while protecting the gate web thus formed in the first and second conductive layers.

13. A method of forming a field-effect transistor, the method comprising:
covering a substrate with a gate dielectric layer and at least one conductive layer;
forming a first web in the at least one conductive layer, the first web forming a bottom part of a gate stack and being separated from further portions of the at least one conductive layer by openings;
forming lightly doped drain regions within the substrate and below the openings;
filling the openings to form spacers therein;
selectively removing the further portions of the at least one conductive layer adjacent to the spacers without removing the web; and
forming highly doped drain regions within the substrate in surface regions where the further portions of the at least one conductive layer have been removed.

14. The method according to claim 13, wherein the at least one conductive layer comprises a polysilicon layer.

15. The method according to claim 13, further comprising forming an isolation in the substrate.

16. The method according to claim 13, wherein the openings are formed having a width of more than 60 nm.

17. The method according to claim 13, wherein the step of filling the openings to form spacers therein comprises depositing one or both of an oxide and/or a nitride such that the openings are completely filled.

18. The method according to claim 17, further comprising planarizing a surface formed by the further portions and the web of the at least one conductive layer and the filling of the openings.

19. The method according to claim 17, further comprising forming sidewall spacers in the openings prior to filling the openings.

20. The method according to claim 18, wherein the at least one conductive layer comprises a first conductive layer, the method further comprising depositing a second conductive layer after planarizing the surface, wherein a second web is formed in the second conductive layer deposited above the first web by removing remaining portions of the second conductive layer during the step of selectively removing the further portions of the first conductive layer.

21. A field-effect transistor, comprising:
a substrate;
a gate dielectric layer over the substrate;
a first gate web over the gate dielectric layer;
spacers adjacent to and on sides of the first gate web, wherein the spacers have a width larger than a width of the first gate web;
lightly doped drain regions formed in the substrate below the spacers; and
highly doped drain regions formed in the substrate adjacent to the lightly doped drain regions.

22. The field-effect transistor according to claim 21, further comprising a second gate web disposed on the first gate web and having a width larger than the width of the first gate web.

23. The field effect transistor according to claim 22, wherein the first gate web and the second gate web comprise polysilicon.

24. The field-effect transistor according to claim 21, wherein the spacers comprise one or both of an oxide and/or a nitride.

25. The field-effect transistor according to claim 21, wherein the first gate web and the spacers have the same height.

26. The field-effect transistor according to claim 21, further comprising a well formed in the substrate.

27. The field-effect transistor according to claim 21, further comprising an isolation formed as a shallow trench filled with isolating material in the substrate in order to define an active area in the substrate for the field-effect transistor.

28. The field-effect transistor according to claim 21, wherein the spacers have a width of more than 60 nm.

29. The field-effect transistor according to claim 21, wherein the spacers have a width of more than 70 nm.

30. The field-effect transistor according to claim 21, wherein the width of the spacers is larger than the height of the first gate web.

31. The field-effect transistor according to claim 21, further comprising conductive contacts electrically connected with each of the highly doped drain regions.

32. A non-volatile memory device, comprising:
an array of memory cells, each of the memory cells comprising a memory cell transistor; and
a field-effect transistor according to claim 21, the field-effect transistor being located in a periphery of the array.

33. The non-volatile memory device according to claim 32, wherein the field-effect transistor is electrically connected to the memory cell transistor in order to apply a voltage of more than 3 V to source/drain regions of the memory cell transistor using a high-voltage source transistor in order to program or erase a logic information stored in the memory cell transistor.

34. A method of operating a non-volatile memory, the method comprising:
providing a non-volatile memory, which comprises a field-effect transistor according claim 21 coupled to at least one memory cell transistor; and
applying a voltage of more than 3 V to source/drain regions of the memory cell transistor using a high-voltage source and the field-effect transistor in order to program or erase a logic information stored in the memory cell transistor.
